(19) United States
(12) Patent Application Publication
(10) Pub. No.: US 2012/0187469 A1
(43) Pub. Date: Jul. 26, 2012

(54) METHOD OF MANUFACTURING SEMICONDUCTOR STORAGE DEVICE AND SEMICONDUCTOR STORAGE DEVICE

(75) Inventors: Katsuyuki SEKINE, Mie (JP); Junya FUJITA, Mie (JP)

(73) Assignee: Kabushiki Kaisha Toshiba, Tokyo (JP)

(21) Appl. No.: 13/238,718

(22) Filed: Sep. 21, 2011

(30) Foreign Application Priority Data
Jan. 25, 2011 (JP) 2011-012874

(51) Int. Cl. H01L 29/788; H01L 21/336

(52) U.S. Cl. 257/321; 438/301; 257/E29.3; 257/E21.422

(57) ABSTRACT

According to one embodiment, there is provided a method of manufacturing a semiconductor storage device. In the method, any one of Ge, Sn, C, and N is introduced as impurity to a surface of a semiconductor substrate. In the method, the semiconductor substrate is thermally oxidized so that a tunnel insulating film is formed on the surface of the semiconductor substrate to which the impurity is introduced. In the method, a gate having a charge accumulation layer is formed on the tunnel insulating film. In the method, impurity diffusion regions are formed in the semiconductor substrate in a self-aligned manner using the gate.

### CROSS-REFERENCE TO RELATED APPLICATIONS

This application is based upon and claims the benefit of priority from Japanese Patent Application No. 2011-012874, filed on Jan. 25, 2011; the entire contents of which are incorporated herein by reference.

### FIELD

Embodiments described herein relate generally to a method of manufacturing a semiconductor storage device, and a semiconductor storage device.

### BACKGROUND

In a nonvolatile semiconductor storage device such as a NAND-type flash memory, electric charges are hardly passed through a tunnel insulating film and a tunnel current is small, when programming is performed for accumulating electric charges in a floating electrode through the tunnel insulating film, and therefore a high program voltage needs to be applied to a control electrode. In order to improve reliability of the semiconductor storage device by increasing a program speed and decreasing a program voltage, the tunnel current through the tunnel insulating film is preferably increased.

### BRIEF DESCRIPTION OF THE DRAWINGS

FIG. 1A and FIG. 1B are views illustrating a structure of a semiconductor storage device according to a first embodiment;

FIG. 2A and FIG. 2B are views illustrating a method of manufacturing a semiconductor storage device according to the first embodiment;

FIG. 3A and FIG. 3B are views illustrating a method of manufacturing a semiconductor storage device according to the first embodiment;

FIG. 4A and FIG. 4B are views illustrating a method of manufacturing a semiconductor storage device according to the first embodiment;

FIG. 5A and FIG. 5B are views illustrating a method of manufacturing a semiconductor storage device according to the first embodiment;

FIG. 6A and FIG. 6B are views illustrating a method of manufacturing a semiconductor storage device according to the first embodiment;

FIG. 7 is a view for describing an effect according to the first embodiment;

FIG. 8A and FIG. 8B are views illustrating a structure of a semiconductor storage device according to a second embodiment; and

FIG. 9A to FIG. 9C are views illustrating an impurity profile according to comparative examples.

FIG. 9D is a view illustrating an impurity profile according to the second embodiment.

### DETAILED DESCRIPTION

In general, according to one embodiment, there is provided a method of manufacturing a semiconductor storage device. In the method, any one of Ge, Sn, C, and N is introduced as impurity to a surface of a semiconductor substrate. In the method, the semiconductor substrate is thermally oxidized so that a tunnel insulating film is formed on the surface of the semiconductor substrate to which the impurity is introduced. In the method, a gate having a charge accumulation layer is formed on the tunnel insulating film. In the method, impurity diffusion regions are formed in the semiconductor substrate in a self-aligned manner using the gate.

Exemplary embodiments of a method of manufacturing a semiconductor storage device, and a semiconductor storage device will be explained below in detail with reference to the accompanying drawings. The present invention is not limited to the following embodiments.

### First Embodiment

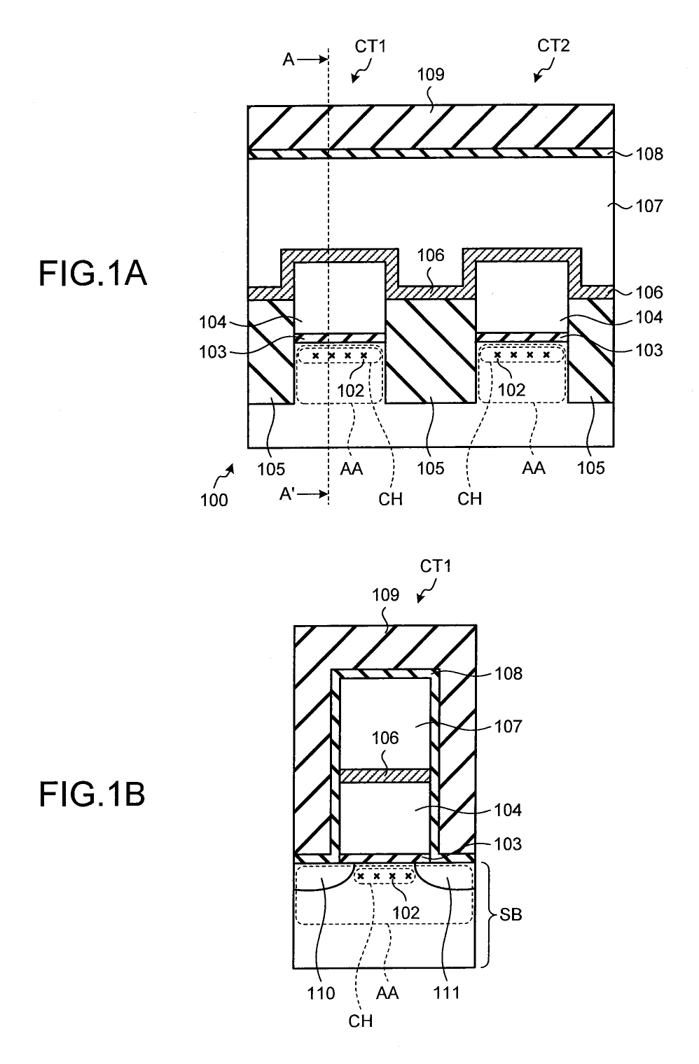

A semiconductor storage device 100 according to a first embodiment will be described, by using FIG. 1A and FIG. 1B. FIG. 1A and FIG. 1B are views of a sectional structure of the semiconductor storage device 100 exemplarily illustrating a case where the semiconductor storage device 100 is a floating gate-type nonvolatile memory. FIG. 1A illustrates a sectional face cut along a longitudinal direction of a word line 107, and FIG. 1B illustrates a sectional face taken along the line A-A′, namely, the sectional face cut along a longitudinal direction of active areas AA.

For example, the semiconductor storage device 100 is a NAND-type flash memory in which a plurality of memory cells are arranged along the longitudinal direction of the active areas AA. In the semiconductor storage device 100, for example, a plurality of cell transistors CT1, CT2, etc., are arranged as memory cells, at positions where a plurality of word lines 107 and a plurality of active areas AA are crossed with each other. Namely, the semiconductor storage device 100 includes a plurality of two-dimensionally arranged cell transistors CT1, CT2, etc., for example. Each active area AA is demarcated by an element separation part 105 in a semiconductor substrate SB. Each word line 107 functions as a control electrode of the corresponding cell transistors CT1, CT2, etc. Therefore, explanation will be given hereafter, with each word line 107 set as a control electrode 107. Further, although the cell transistor CT1 will be exemplarily described hereafter, the description will also be applicable to the other cell transistor CT2, etc.

The cell transistor CT1 includes a region CH to be a channel, impurity diffusion regions 110, 111, a tunnel insulating film 103, a charge accumulation layer 104, an inter-electrode insulating film 106, a control electrode 107, and a side wall insulating film 108.

The region CH to be a channel, is demarcated by the impurity diffusion regions 110, 111 in the active area AA (see FIG. 1B). The region CH to be a channel, is a region in which a channel is formed when the cell transistor CT1 is operated. The active area AA is demarcated by the element separation part 105 in the semiconductor substrate SB. The element separation part 105 electrically separates one active area AA from other active areas AA. The element separation part 105 has a STI-type structure and is made of an insulating material (such as silicon oxide). The region CH to be a channel, is made of a semiconductor (such as silicon) including, for example, a first conductive type (such as P-type) impurity (such as B).

Further, any one of Ge, Sn, C is contained in the region CH to be a channel as impurity 102. The impurity 102 is the impurity for modulating a workfunction (increase a tunnel current) of the region CH to be a channel. Elements of Ge, Sn, C are capable of effectively reducing the workfunction of the region CH to be a channel, and are hardly educed from a semiconductor (such as silicon). Ge has a merit that a channel resistance can be reduced simultaneously with modulation of the workfunction (increase of a tunnel current). C has a workfunction modulation (tunnel current increase) effect larger than others (namely, Ge, Sn).

The impurity diffusion regions 110, 111 are arranged adjacent to the region CH to be a channel in the active area AA (see FIG. 1B). The impurity diffusion regions 110, 111 are the regions that function as a source or a drain of the cell transistor CT1 when the cell transistor CT1 is operated. The impurity diffusion regions 110, 111 are made of the semiconductor (such as silicon) including, for example, a second conductive type (such as N-type) impurities (such as P, As, Sb). The second conductive type impurities are contained in the impurity diffusion regions 110, 111, at a higher concentration than a concentration of the first conductive type impurities in the region CH to be a channel.

The tunnel insulating film 103 covers the region CH to be a channel. The tunnel insulating film 103 is made of an insulating material (such as silicon oxide). The tunnel insulating film 103 is the film for tunneling electric charges (such as electrons) between the region CH to be a channel, and the charge accumulation layer 104, when the cell transistor CT1 is operated. A thickness of the tunnel insulating film 103 is 5 nm to 10 nm for example.

The charge accumulation layer 104 is a floating electrode, and covers the tunnel insulating film 103. The charge accumulation layer 104 accumulates the electric charges tunneled from the region CH to be a channel, through the tunnel insulating film 103. The charge accumulation layer 104 is made of a semiconductor (such as amorphous silicon, polysilicon, and silicon germanium) including the second conductive type (such as N-type) impurities for example, or the charge accumulation layer 104 may be made of a metal-based material. A thickness of the charge accumulation layer is 30 nm to 80 nm for example.

The inter-electrode insulating film 106 covers the charge accumulation layer 104. The inter-electrode insulating film 106 has a function of preventing (suppressing) the electric charges accumulated in the charge accumulation layer 104, from leaking to the control electrode 107. The inter-electrode insulating film 106 may be formed by a single layer of a silicon oxide film or a silicon nitride film for example, or may be formed by a laminated layer of the silicon oxide film and/or the silicon nitride film. For example, the inter-electrode insulating film 106 may be formed by an ONO film (silicon oxide film/silicon nitride film/silicon oxide film), or the inter-electrode insulating film 106 may be formed by a metal compound-based insulating film or a high dielectric insulating film. A thickness of the inter-electrode insulating film 106 is 5 nm to 20 nm for example.

The control electrode 107 covers the inter-electrode insulating film 106. The control electrode 107 functions as a gate electrode for controlling an operation of the cell transistor CT1. The control electrode 107 is formed by a semiconductor (such as polysilicon) including the second conductive type (such as N-type) impurities, or the control electrode 107 may be made of a metal-based material (such as tungsten).

A side wall insulating film 108 covers an upper face and a side face of the control electrode 107, a side face of the inter-electrode insulating film 106, aside face of the charge accumulation layer 104, and a side face of the tunnel insulating film 103, along a longitudinal direction of the control electrode 107 (see FIG. 1B). Thus, the side wall insulating film 108 protects side walls of the control electrode 107 and the charge accumulation layer 104. The side wall insulating film 108 is made of an insulating material (such as silicon oxide). The side wall insulating film 108 is covered with an inter-layer insulating film 109. The inter-layer insulating film 109 insulates gates of the cell transistor CT1 and other longitudinally adjacent cell transistors (not illustrated) from each other in the longitudinal direction of the active area AA, and also insulates the cell transistor CT1 and an upper wiring (not illustrated) from each other. The inter-layer insulating film 109 is made of the insulating material (such as silicon oxide).

Thus, the region CH to be a channel, has the impurity 102 for modulating the workfunction (increasing the tunnel current) of the region CH to be a channel. Thus, when the cell transistor CT1 is operated (particularly, when the cell transistor CT1 is program-operated), the tunnel current through the tunnel insulating film 103 can be easily increased.

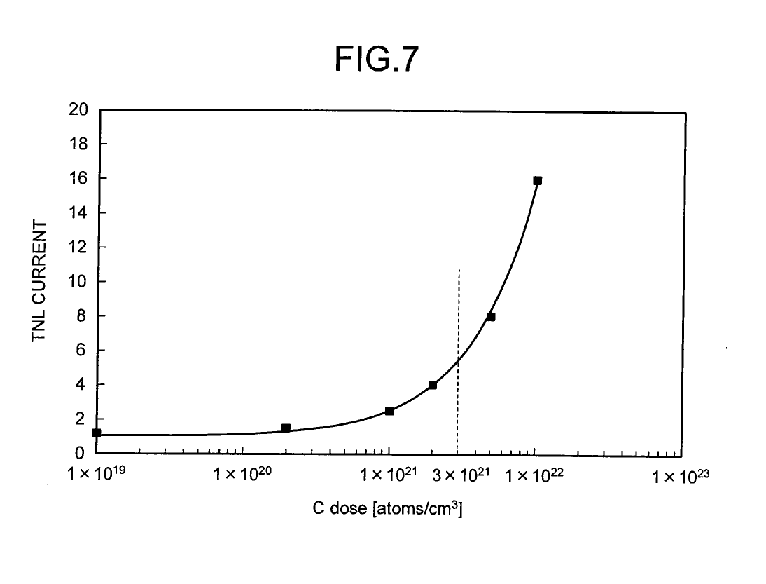

For example, when inventors of the present invention conducts an experiment regarding a case that C is introduced to the region CH to be a channel, as the impurity 102, results can be obtained as illustrated in FIG. 7. Namely, the tunnel current through the tunnel insulating film was measured in a case that a plurality of samples were prepared, the samples including cell transistors with varied concentrations of the impurity 102 in the region CH to be a channel, and a constant voltage was applied to the control electrode of the cell transistor in each sample. As a result, as illustrated in FIG. 7, it was confirmed that when the region to be a channel, included C at a concentration of 3×10²¹ atoms/cm³ or more, the tunnel current through the tunnel insulating film 103 could be easily increased.

Thus, the tunnel current through the tunnel insulating film 103 can be easily increased, and therefore further higher speed of a program speed is achieved, program windows can be increased, and a program voltage can be decreased. Therefore, memory cells with excellent reliability can be realized.

Note that in the above description, an example of the semiconductor storage device 100 is given, being the floating gate-type nonvolatile memory, in which a floating electrode is formed as the charge accumulation layer 104 for accumulating electric charges thereon. However, a similar effect can be obtained even if applied to a MONOS-type nonvolatile memory. In the MONOS-type nonvolatile memory, the similar effect can be obtained in either type of a planar type or a 3D (gate-all-around) type. Note that in the MONOS-type nonvolatile memory, for example as illustrated in FIG. 1A and FIG. 1B, when a portion at least in contact with the charge accumulation layer 104 in each of the tunnel insulating film 103 and the inter-electrode insulating film 106, is made of a material mainly composed of silicon oxide for example, the charge accumulation layer 104 made of a material mainly composed of silicon nitride for example, accumulates thereon electric charges tunneled from the region CH to be a channel through the tunnel insulating film 103.

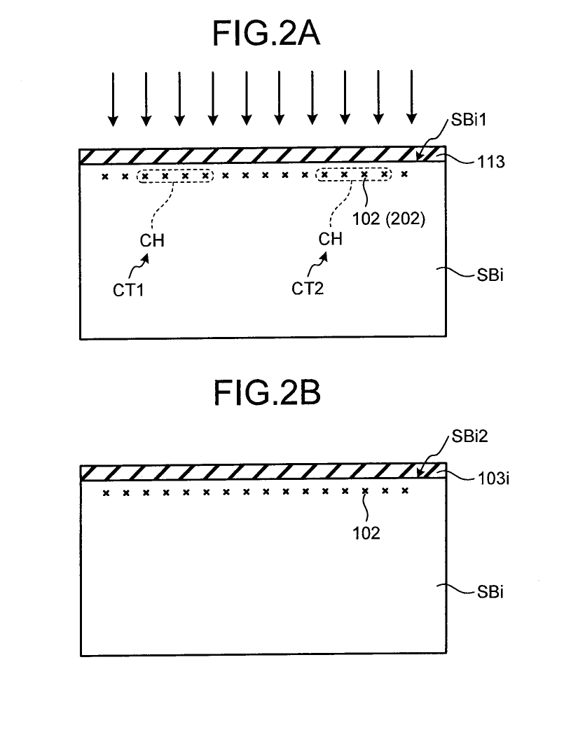

Next, the method of manufacturing the semiconductor storage device 100 will be described by using FIG. 2A to FIG. 6B. FIG. 2A to FIG. 6B are step sectional views illustrating the method of manufacturing the semiconductor storage device 100.

In the step illustrated in FIG. 2A, a semiconductor substrate SBi is prepared. The semiconductor substrate SBi is obtained by forming a P-type well on a P-type silicon substrate or N-type silicon substrate for example. Then, a sacrificial insulating film 113 for performing ion implantation in a subsequent step, is formed on the semiconductor substrate SBi. The sacrificial insulating film 113 is formed by a silicon oxide film for example.

The impurity 102 of elements (such as Ge, Sn, C, etc.) for modulating the workfunction are introduced to the vicinity of a surface SBi1 in a semiconductor substrate SBi including the region CH to be a channel, of the cell transistors CT1, CT2, etc., to be formed. Specifically, any one of the ions of Ge, Sn, and C is implanted by an ion implantation method, to the surface SBi1 in the semiconductor substrate SBi through the sacrificial insulating film 113. Then, annealing is applied thereto at 1050° C. for example, for recovering from damage (crystal defect, etc.) in the semiconductor substrate SBi, due to ion implantation.

Note that instead of introducing the impurity 102 to the surface SBi1 of the semiconductor substrate SBi by the ion implantation method, gas to be the impurity 102 may be supplied to the surface SBi1 of the semiconductor substrate SBi, and the impurity 102 may be introduced to the surface SBi1 of the semiconductor substrate SBi. Alternatively, a silicon thin film containing the impurity 102 is formed on the surface SBi1 of the semiconductor substrate SBi by a CVD (chemical vapor deposition) method, and the impurity 102 may be introduced to the surface SBi1 of the semiconductor substrate SBi. In a case of the planar type cell, any one of the methods can be used. However, in a case of the 3D-type cell, the vapor diffusion method and the CVD method are preferably used.

In the step illustrated in FIG. 2B, the sacrificial insulating film 113 is peeled off by diluted hydrofluoric acid. After peeling off the sacrificial insulating film 113, the semiconductor substrate SBi is thermally oxidized at approximately 1000° C. for example. Namely, a tunnel insulating film 103i is formed on a surface SBi2 of a semiconductor substrate SBi to which the impurity 102 are introduced, using a thermal oxidation method. The tunnel insulating film 103i is formed to have a thickness of about 3 nm to 10 nm for example.

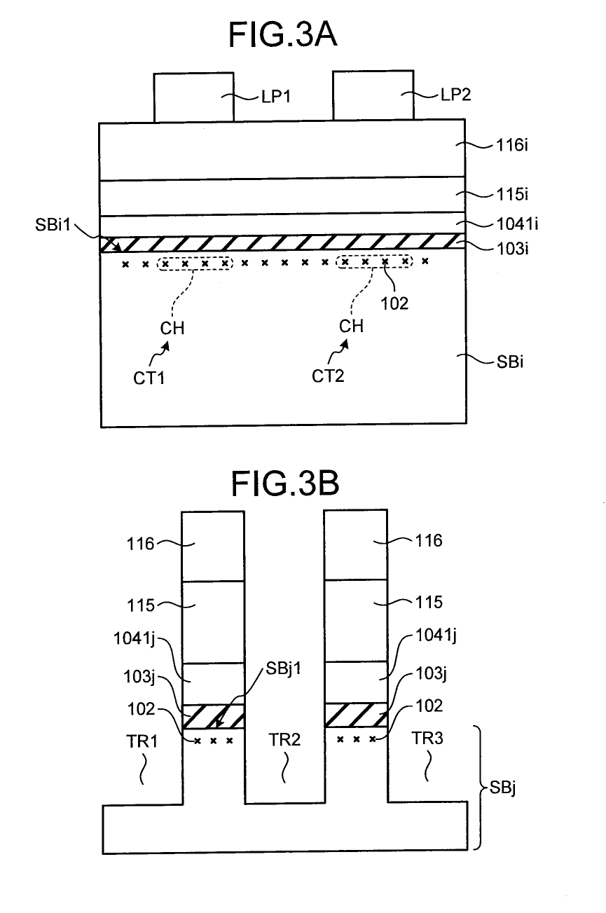

In the step illustrated in FIG. 3A, a conductive film 1041i, being a lower part (conductive film 1041) of the charge accumulation layer 104 is formed on the tunnel insulating film 103i by the CVD method of example, (so as to cover the tunnel insulating film 103i). The conductive film 1041i is formed by a semiconductor (such as amorphous silicon, polysilicon, and silicon germanium) including the second conductive type (such as N-type) impurity. The conductive film 1041i is formed to have a thickness of about 10 nm to 100 nm for example.

Subsequently, for example by the CVD method, a silicon nitride film 115i is formed on the conductive film 1041i in a thickness of about 50 nm to 200 nm for example. Then, for example by the CVD method, a silicon oxide film 116i is formed on the silicon nitride film 115i in a thickness of about 50 nm to 400 nm. A surface of the silicon oxide film 116i is coated with photoresist, and patterning is applied to the photoresist by an exposure operation, thus forming a resist pattern including a plurality of line patterns LP1, LP2, etc., respectively extending in the longitudinal direction of the active area AA to be formed, being the resist pattern corresponding to the cell transistors CT1, CT2, etc., to be formed.

In the step illustrated in FIG. 3B, etching is applied to the silicon oxide film 116i (see FIG. 3A), with the resist pattern used as an etching mask. Namely, the line patterns are transferred to the silicon oxide film 116i. The resist patterns (a plurality of line patterns LP1, LP2, etc.) are removed after etching.

Then, etching is applied to the silicon nitride film 115i, the conductive film 1041i, the tunnel insulating film 103i, and the semiconductor substrate SBi, with the silicon oxide film 116 used as a mask (namely, a hard mask), thus forming a silicon nitride film 115 to which the line patterns are transferred, a conductive film 1041j, and a tunnel insulating film 103j, and also forming grooves TR1 to TR3 on a surface SBj1 of the semiconductor substrate SBj.

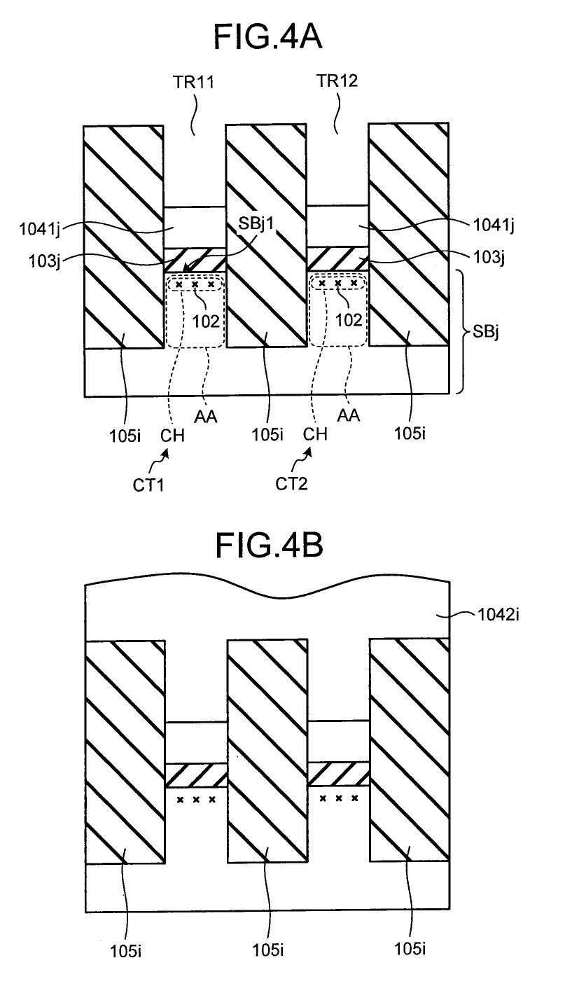

In the step of illustrated in FIG. 4A, for example by the CVD method, the grooves TR1 to TR3 are embedded with the insulating material (such as silicon oxide) in a thickness of about 200 nm to 1500 nm for example, thus forming an element separation part 105i for demarcating the active area AA in the surface SBj1 of the semiconductor substrate SBj and thereon. The active area AA demarcated by the element separation part 105i includes the region CH to be a channel corresponding to the cell transistors CT1, CT2, etc.

Then, the silicon oxide film 116 is removed by a CMP method (Chemical Mechanical Polishing method), and an upper surface of the embedded insulating material is planarized. At this time, planarization is performed, with the silicon nitride film 115 as a stopper. Subsequently, the silicon nitride film 115 is selectively removed, using a method (for example, a dry etching method using radical of a mixed gas of CF₄ and O₂, and H₂O) capable of selectively applying etching to the silicon nitride film 115.

In the step illustrated in FIG. 4B, grooves TR11, TR12 (see FIG. 4A) obtained after removing the silicon nitride film 115 are embedded with a conductive material (such as polysilicon) by the CVD method of example, thus forming a conductive film 1042i to be an upper part (a conductive film 1042) of the charge accumulation layer 104.

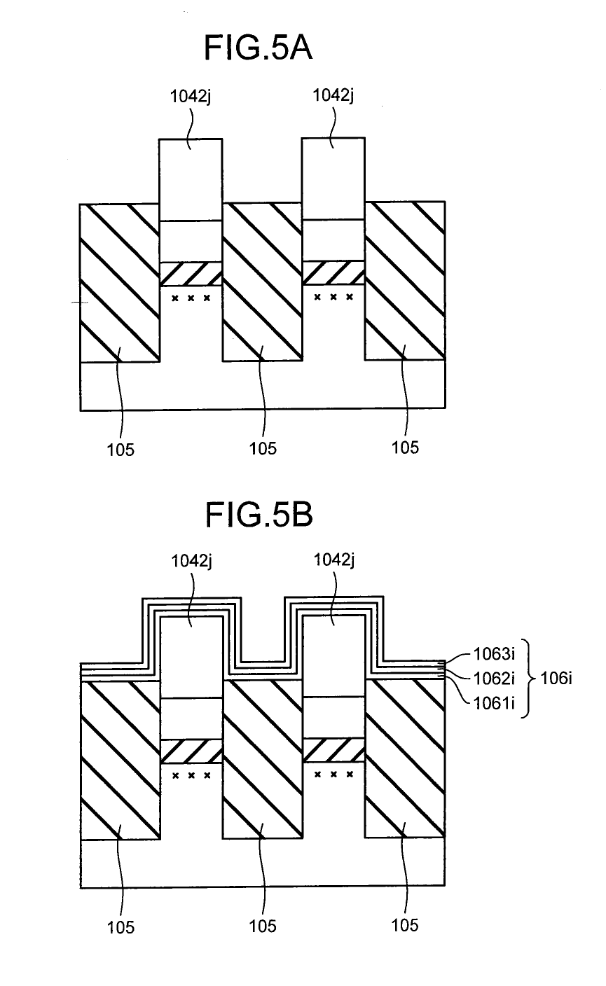

In the step illustrated in FIG. 5A, for example by the CMP method, planarization of the conductive film 1042i is performed, with the element separation part 105i as a stopper. Then, etching-back is applied to the element separation part 105i, so that the upper surface of the element separation part 105 is made lower than the upper surface of the conductive film 1042j.

In the step illustrated in FIG. 5B, for example by the CVD method, an inter-electrode insulating film 106i is formed so as to cover the conductive film 1042j and the element separation part 105. The inter-electrode insulating film 106i is formed by the ONO film (silicon oxide film 1061i/silicon nitride film 1062i/silicon oxide film 1063i) for example. Namely, the silicon oxide film 1061i, the silicon nitride film 1062i, and the silicon oxide film 1063i are sequentially deposited so as to cover the conductive film 1042j and the element separation part 105. At this time, a total thickness of the inter-electrode insulating film 106i is set to 5 nm to 20 nm for example.

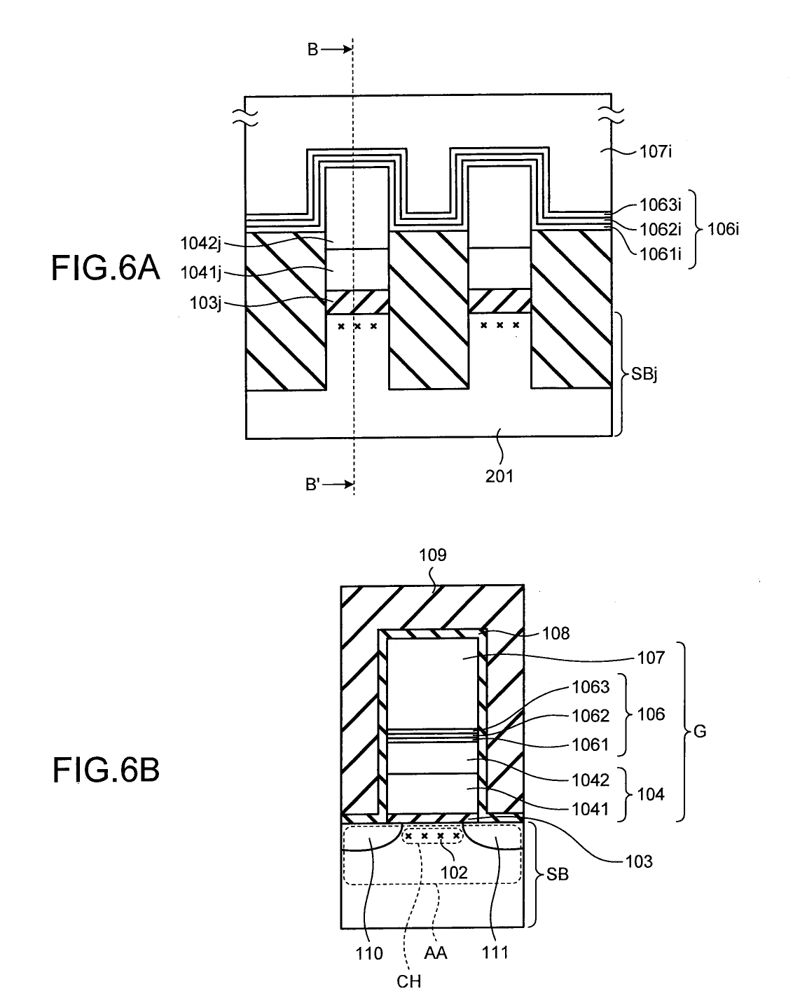

In the step illustrated in FIG.6A, a conductive film 107i to be the control electrode 107 is formed on the inter-electrode insulating film 106i (so as to cover the inter-electrode insulating film 106i) by a conductive material (such as polysilicon) using the CVD method of example. Then, an insulating film such as a silicon oxide film (not illustrated) to be a hard mask for processing, is formed, which is then coated with photoresist, and the resist is patterned by an exposure operation, thus forming a resist pattern (not illustrated) including a plurality of line patterns respectively extending in a direction crossing the longitudinal direction of the active area AA (namely, a direction along the control electrode 107 to be formed).

In the step illustrated in FIG. 6B, the line patterns are transferred to the insulating film, to thereby form a patterned insulating film. Then, etching is applied to the conductive film 107i, the inter-electrode insulating film 106i (silicon oxide film 1063i, silicon nitride film 1062i, and silicon oxide film 1061i), the conductive film 1042j, the conductive film 1041j, and the tunnel insulating film 103j, with the patterned insulating film used as a mask (namely, a hard mask), thus forming a gate electrode G with the charge accumulation layer 104, the inter-electrode insulating film 106, and the control electrode 107 sequentially laminated thereon, and the tunnel insulating film 103 corresponding to the gate electrode G. The inter-electrode insulating film 106 has the silicon oxide film 1061, the silicon nitride film 1062, and the silicon oxide film 1063 sequentially laminated thereon. Also, the charge accumulation layer 104 has the conductive film 1041 and the conductive film 1042 sequentially laminated thereon.

Next, ion implantation is carried out, with the gate electrode G used as a mask, thus forming the impurity diffusion regions 110, 111 to be a source or a drain in the active area AA in the semiconductor substrate SB, in such manner as being self-aligned with the gate electrode G. Wherein, a region demarcated by the impurity diffusion regions 110, 111 in the active area AA is defined as the region CH to be a channel.

Then, the side wall insulating film 108 is formed by silicon oxide for example, so as to cover the upper face and side face of the control electrode 107, the side face of the inter-electrode insulating film 106, the side face of the charge accumulation layer 104, and the side face of the tunnel insulating film 103, along the longitudinal direction of the control electrode 107 (see FIG. 1B). Then, the inter-layer insulating film 109 is formed by silicon oxide for example, so as to cover the side wall insulating film 108.

Further, the semiconductor storage device 100 as illustrated in FIG. 1 is obtained through an ordinary wiring step, etc. Namely, any one of the Ge, Sn, and C is contained in the region CH to be a channel as the impurity 102, in each of the cell transistors CT1, CT2 of the semiconductor storage device 100.

Consider a case where in the step illustrated in FIG. 2A S and F are introduced to the vicinity of the surface SBi1 in the semiconductor substrate SBi as the impurities for modulating the workfunction (increasing the tunnel current.) In this case, S and F are likely to escape from the semiconductor substrate SBi when the semiconductor substrate SBi is thermally oxidized in the step illustrated in FIG. 2B. Thus, it is difficult to obtain the semiconductor storage device 100 including impurities for modulating the workfunction (increasing the tunnel current) in the region CH to be a channel, thereby also making it difficult to increase the tunnel current passing through the tunnel insulating film.

Meanwhile, according to the first embodiment, in the step illustrated in FIG. 2A, any one of the Ge, Sn, C is introduced to the vicinity of the surface SBi1 in the semiconductor substrate SBi, as the impurity 102 for modulating the workfunction (increasing the tunnel current). Thus, in the step illustrated in FIG. 2B, it is easy that the impurity 102 stays in the semiconductor substrate SBi when the semiconductor substrate SBi is thermally oxidized. Accordingly, the semiconductor storage device 100 including the impurity 102 for modulating the workfunction (increasing the tunnel current) in the region CH to be a channel, can be obtained. As a result, the workfunction of the region CH to be a channel can be reduced, and therefore a barrier height of the tunnel insulating film 103 with respect to the electric charges can be effectively decreased. Accordingly, even in a case of a small introduction amount, the tunnel current passing through the tunnel insulating film 103 can be easily increased when the cell transistor CT1 is operated (particularly program-operated).

Further, the element introduced as the impurity 102 for modulating the workfunction (such as Ge, Sn, C, etc.) can stay in the whole part of the surface SBi1 in the semiconductor substrate SBi including the region CH to be a channel. Therefore, the semiconductor storage device 100 containing the impurity 102 in the region CH to be a channel, can be obtained at a uniform concentration when compared between adjoining cells (cell transistors). As a result, the tunnel current passing through the tunnel insulating film 103 can be easily increased, while suppressing a variation in the tunnel current between adjoining cells. Further, since the tunnel current passing through the tunnel insulating film 103 can be easily increased, a faster program speed can be achieved, program windows can be increased, and a program voltage can be decreased. Therefore memory cells with excellent reliability can be realized.

Alternatively, consider a case where the semiconductor substrate SBi prepared by the step illustrated in FIG. 2A is made of SiC. In this case, since the semiconductor substrate SBi with a large diameter can not be made (prepared) at a low cost, there is a possibility that a manufacturing cost of the semiconductor storage device 100 is increased.

Meanwhile, in the first embodiment, the semiconductor substrate SBi prepared by the step illustrated in FIG. 2A is made of silicon (Si). Thus, since the semiconductor substrate SBi with a large diameter can be made (prepared) at a low cost, the manufacturing cost of the semiconductor storage device 100 can be reduced.

Further, when the semiconductor substrate SBi prepared by the step illustrated in FIG. 2A is made of SiC or SiGe, the tunnel insulating film (tunnel oxide film) excellent in quality and having dielectric strength voltage of 10 MV/cm or more is hardly obtained in the step illustrated in FIG. 2B, even if a high temperature step is used. Therefore, it is extremely difficult to form a nonvolatile memory on a SiC/SiGe substrate, for writing/erasing data by applying high voltage thereto.

Meanwhile, in the first embodiment, the semiconductor substrate SBi prepared by the step illustrated in FIG. 2A is made of silicon (Si). Therefore, in order to form the tunnel insulating film (tunnel oxide film) 103i which is excellent in quality by the thermal oxidation method in the step illustrated in FIG. 2B, it is sufficient to thermally oxidize the semiconductor substrate SBi at about 1000° C. Further, it is also sufficient to perform annealing at about 1050° C., for recovering from the damage (crystal defect, etc.,) due to ion implantation in the semiconductor substrate SBi, because the semiconductor substrate SBi is made of silicon (Si). Thus, diffusion of the impurity 102 caused by the thermal oxidation and annealing can be suppressed, and therefore it is easy to form each cell transistor in a tiny size. Further, the tunnel insulating film 103 practically having a sufficient dielectric strength voltage can be formed.

### Second Embodiment

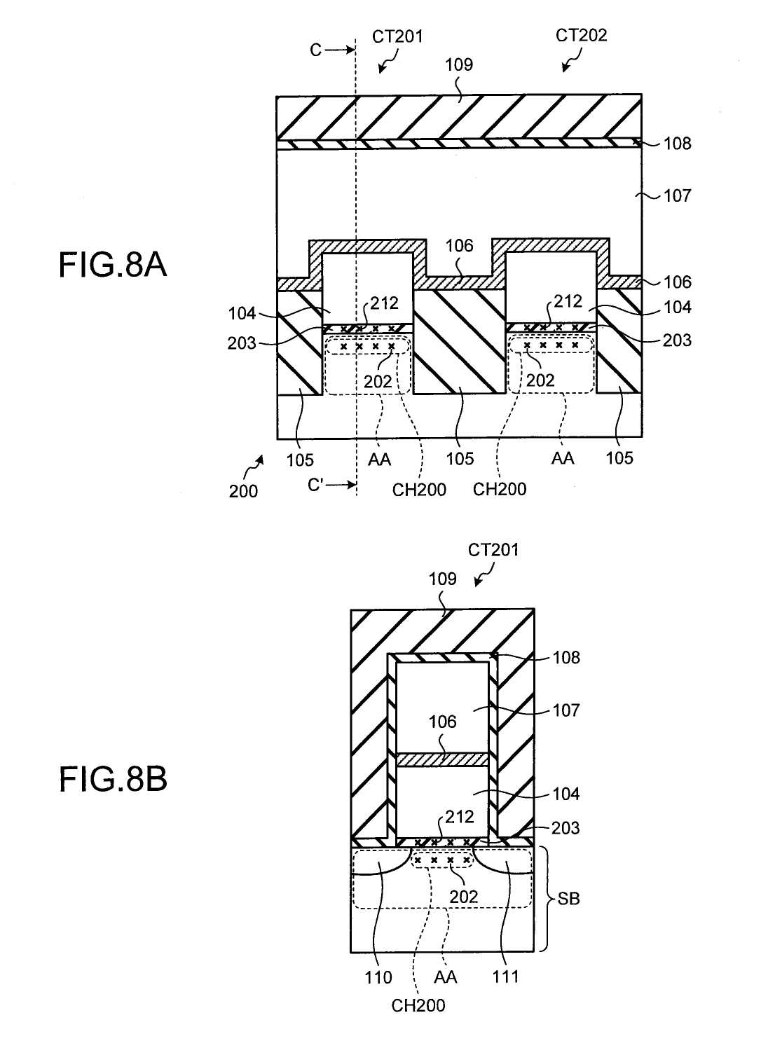

Next, a semiconductor storage device 200 according to a second embodiment will be described, using FIG. 8A and FIG. 8B.

FIG. 8A and FIG. 8B are views exemplarily illustrating a sectional structure of the semiconductor storage device 200 in a case that the semiconductor storage device 200 is the floating gate type nonvolatile memory. FIG. 8A illustrates a sectional face cut along the longitudinal direction of the control electrode (word line) 107, and FIG. 8B illustrates a sectional face cut along the line C-C′, namely, cut along the longitudinal direction of the active area AA. Explanation will be focused on a portion different from the first embodiment.

The first embodiment shows an example of introducing the impurity 102 for modulating the workfunction, to the region CH to be a channel. Meanwhile, in the second embodiment, impurity 212 to be positive fixed electric charges is contained in a tunnel insulating film 203 by previously introducing impurity 202 to the region CH200 to be a channel. For example, N (nitrogen) can be given as the impurity 212 to be positive fixed electric charges in the tunnel insulating film 203.

Namely, each of cell transistors CT201, 202 in the semiconductor storage device 200 includes a region CH200 to be a channel, and the tunnel insulating film 203.

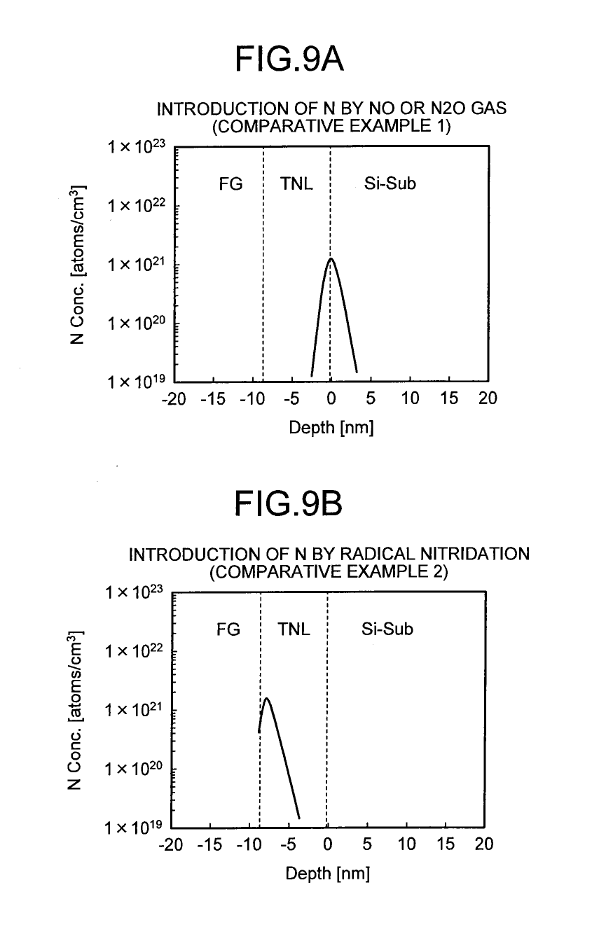

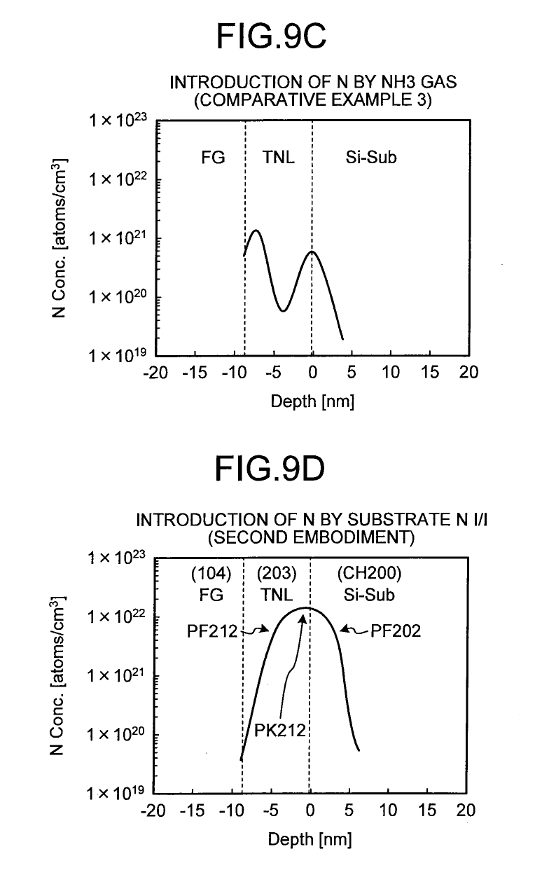

N (nitrogen) is contained in the region CH200 to be a channel, as the impurity 202. The impurity 202 is the impurity previously introduced to the region CH200, so that the impurity 212 is contained in the tunnel insulating film 203. Specifically, as illustrated in FIG. 9D, the region CH200 to be a channel, has an impurity profile PF202 including N as the impurity 202 continuously from a side of the tunnel insulating film 203 to an internal side of the semiconductor substrate SB. In the impurity profile PF202, concentration of the impurity is gradually decreased from the side of the tunnel insulating film 203 to the internal side of the semiconductor substrate SB. Further, the impurity profile PF202 continues to an impurity profile PF212 on an interface between the region CH200 to be a channel and the tunnel insulating film 203.

N (nitrogen) is contained in the tunnel insulating film 203 as the impurity 212. The impurity 212 is the impurity to be positive fixed electric charges in the tunnel insulating film 203. Specifically, as illustrated in FIG. 9D, the tunnel insulating film 203 has an impurity profile PF212 including the impurity 212 continuously from the side of the region CH200 to be a channel, to the side of the charge accumulation layer 104. The impurity profile PF212 has a broad peak PK212 on the side of the region CH200 to be a channel. Further, in the impurity profile PF212, an impurity concentration is gradually decreased from a position of the peak PK212 toward the charge accumulation layer 104 in the tunnel insulating film 203.

Further, in the method of manufacturing the semiconductor storage device 200 according to the second embodiment, N (nitrogen) is introduced to the vicinity of the surface SBi1 in the semiconductor substrate SBi by an ion implantation method for example in the step illustrated in FIG. 2A. Then, the impurity 202 in the region CH200 to be a channel is thermally diffused into the tunnel insulating film 203, when the tunnel insulating film 203 is formed by the thermal oxidation method, similarly to the step illustrated in FIG. 2B.

Consider a case (comparative example 1) where, without introducing N (nitrogen) to the region CH to be a channel in the step illustrated in FIG. 2A, N (nitrogen) is introduced to the interface between the tunnel insulating film and the semiconductor substrate using NO gas or N₂O gas after the tunnel insulating film is formed in the step illustrated in FIG. 2B. In this case, as illustrated in FIG. 9A, N hardly enters into a region other than the vicinity of the interface between the tunnel insulating film and the semiconductor substrate, thus making it impossible to introduce N to a major part of the region in the tunnel insulating film. Accordingly, a desired concentration of N effective to increase the tunnel current is hardly obtained.

Alternatively, consider a case (comparative example 2) where, without introducing N (nitrogen) to the region CH to be a channel in the step illustrated in FIG. 2A, N (nitrogen) is introduced to the tunnel insulating film by applying radical nitridation thereto after the tunnel insulating film is formed in the step illustrated in FIG. 2B. In this case, as illustrated in FIG. 9B, N hardly enters into a region other than the vicinity of the surface on a floating electrode side in the tunnel insulating film, thus making it impossible to introduce N to a major part of the region in the tunnel insulating film. Accordingly, a desired concentration of N effective to increase the tunnel current is hardly obtained.

Alternatively, consider a case (comparative example 3) where, without introducing N (nitrogen) to the region CH to be a channel in the step illustrated in FIG. 2A, N (nitrogen) is introduced to the tunnel insulating film by applying nitridation using NH₃ gas after the tunnel insulating film is formed in the step illustrated in FIG. 2B. In this case, as illustrated in FIG. 9C, N hardly enters into a region other than the vicinity of the interface between the tunnel insulating film and the semiconductor substrate, and the vicinity of the surface of the floating electrode side in the tunnel insulating film. Therefore, it is impossible to substantially introduce N to a major part of the region in the tunnel insulating film. Accordingly, a desired concentration of N effective to increase the tunnel current is hardly obtained.

Meanwhile, according to the second embodiment, N (nitrogen) is introduced, for example by an ion implantation method, to the vicinity of the surface SBi1 in the semiconductor substrate SBi in the step illustrated in FIG. 2A, and the introduced impurity 202 in the region CH200 to be a channel is thermally diffused into the tunnel insulating film 203 when the tunnel insulating film 203 is formed by the thermal oxidation method. Thus, the tunnel insulating film 203 has the impurity profile PF212 including N as the impurity 212 continuously from the side of the region CH200 to be a channel to the side of the charge accumulation layer 104. Namely, the impurity 212 to be positive fixed electric charges is contained in the tunnel insulating film 203 over an entire body of the tunnel insulating film 203, and therefore a barrier height of the tunnel insulating film 203 with respect to the electric charges, can be effectively decreased. Thus, the tunnel current passing through the tunnel insulating film 203 can be easily increased.

Specifically, the impurity profile PF212 has the broad peak PK212 on the side of the region CH200 to be a channel. Namely, further much N (nitrogen) can be contained not only in the vicinity of the interface between the tunnel insulating film 203 and the semiconductor substrate, but also in the tunnel insulating film 203 as compared to comparative examples 1 to 3. Thus, the tunnel current passing through the tunnel insulating film 203 can be easily increased when programs are operated, while suppressing the leak of the electric charges accumulated in the charge accumulation layer 104.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor storage device, comprising:
introducing any one of Ge, Sn, C, and N as impurity to a surface of a semiconductor substrate;
thermally oxidizing the semiconductor substrate, so that a tunnel insulating film is formed on the surface of the semiconductor substrate to which the impurity is introduced;
forming a gate having a charge accumulation layer on the tunnel insulating film; and
forming impurity diffusion regions in the semiconductor substrate in a self-aligned manner using the gate.

2. The method of manufacturing a semiconductor storage device according to claim 1, wherein
the forming of the impurity diffusion regions includes demarcating, as a region to be a channel, a region in a lower part of the gate on the surface of the semiconductor substrate and between the impurity diffusion regions.

3. The method of manufacturing a semiconductor storage device according to claim 1, wherein
the introducing of the impurity includes implanting an ion of any one of Ge, Sn, and C into the surface of the semiconductor substrate, by an ion implantation method.

4. The method of manufacturing a semiconductor storage device according to claim 1, wherein
the introducing of the impurity includes supplying gas containing any one of Ge, Sn, and C to the surface of the semiconductor storage device, by a vapor diffusion method.

5. The method of manufacturing a semiconductor storage device according to claim 1, wherein
the introducing of the impurity includes forming a semiconductor film containing any one of Ge, Sn, and C on the surface of the semiconductor substrate, by a CVD method.

6. The method of manufacturing a semiconductor storage device according to claim 1, wherein
the introducing of the impurity includes introducing as the impurity any one of Ge, Sn, and C to the surface of the semiconductor substrate, and
the semiconductor substrate is formed by a material mainly composed of silicon.

7. The method of manufacturing a semiconductor storage device according to claim 1, wherein
the introducing of the impurity includes implanting N-ion into the surface of the semiconductor substrate, by an ion implantation method.

8. The method of manufacturing a semiconductor storage device according to claim 1, wherein
the introducing of the impurity includes introducing N-impurity to the surface of the semiconductor substrate, and
the thermally oxidizing includes thermally diffusing the N-impurity into the tunnel insulating film from the semiconductor substrate.

9. A semiconductor storage device, comprising:
a region to be a channel arranged on a surface of a semiconductor substrate;
a tunnel insulating film which covers the region to be a channel;
a charge accumulation layer which covers the tunnel insulating film;
an inter-electrode insulating film which covers the charge accumulation layer; and
a control electrode which covers the inter-electrode insulating film,
wherein the region to be a channel contains any one of Ge, Sn, and C as impurity.

10. The semiconductor storage device according to claim 9, wherein
the region to be a channel contains C as the impurity.

11. The semiconductor storage device according to claim 10, wherein
the region to be a channel contains C at a concentration of 3×10²¹ atoms/cm³ or more.

12. The semiconductor storage device according to claim 9, wherein
the region to be a channel contains Ge as the impurity.

13. The semiconductor storage device according to claim 9, wherein
the charge accumulation layer is a floating electrode.

14. The semiconductor storage device according to claim 9, wherein
at least a portion of the tunnel insulating film is formed of a material mainly composed of silicon oxide, the portion being in contact with the charge accumulation layer,
at least a portion of the inter-electrode insulating film is formed of a material mainly composed of silicon oxide, the portion being in contact with the charge accumulation layer, and
the charge accumulation layer is formed of a material mainly composed of silicon nitride.

15. The semiconductor storage device according to claim 9, wherein
the semiconductor substrate is formed of a material mainly composed of silicon.

16. A semiconductor storage device, comprising:
a region to be a channel arranged on a surface of a semiconductor substrate;
a tunnel insulating film which covers the region to be a channel;
a charge accumulation layer which covers the tunnel insulating film;
an inter-electrode insulating film which covers the charge accumulation layer; and
a control electrode which covers the inter-electrode insulating film,
wherein the tunnel insulating film has a first impurity profile including N as impurity continuously from a side of the region to be a channel to a side of the charge accumulation layer, and
the first impurity profile has a peak on the side of the region to be a channel.

17. The semiconductor storage device according to claim 16, wherein
the first impurity profile has a profile where a concentration is gradually decreased from a position of the peak in the tunnel insulating film toward the charge accumulation layer.

18. The semiconductor storage device according to claim 16, wherein
the region to be a channel has a second impurity profile including N as impurity continuously from the first impurity profile of the tunnel insulating film.

19. The semiconductor storage device according to claim 18, wherein
the second impurity profile has a profile where a concentration is gradually decreased in the region to be a channel as going away from the tunnel insulating film.

20. The semiconductor storage device according to claim 16, wherein
the charge accumulation layer is a floating electrode.
